(19) United States
(12) Patent Application Publication
(10) Pub. No.: US 2008/0061356 A1
(43) Pub. Date: Mar. 13, 2008

(54) EEPROM DEVICE AND METHODS OF FORMING THE SAME

(76) Inventors: Jae-Hwang Kim, Yongin-si (KR); Kong-Sam Jang, Yongin-si (KR); Yong-Tae Kim, Yonging-si (KR)

Correspondence Address: F. CHAU & ASSOCIATES, LLC, 130 WOODBURY ROAD, WOODBURY, NY, 11797, US

(21) Appl. No.: 11/775,596

(22) Filed: Jul. 10, 2007

(30) Foreign Application Priority Data
Sep. 7, 2006 (KR) 10-2006-86357

(51) Int. Cl. H01L 29/788; H01L 21/336

(52) U.S. Cl. 257/316; 438/257; 257/E29.3; 257/E21.409

(57) ABSTRACT

An EEPROM device is provided with an active region including a first region, a second region having a lower top surface than a top surface of the first region, and a sidewall disposed at the boundary between the first and second regions. A tunneling region of charges for a program operation and/or an erase operation is defined within the sidewall.

### CROSS-REFERENCE TO RELATED APPLICATION

This application claims priority under 35 U.S.C § 119 to Korean Patent Application 10-2006-86357 filed on Sep. 7, 2006, the entire contents of which is hereby incorporated by reference.

### BACKGROUND OF THE INVENTION

1. Technical Field

The present invention relates to EEPROM, and more particularly, to an EEPROM device and methods of forming the same.

2. Discussion of the Related Art

Among semiconductor devices, electrical erasable programmable ROM devices (EEPROMs) are non-volatile memory devices which retain their stored data even when their power supplies are interrupted. One example of an EEPROM devices is a 2T EEPROM device in which a unit cell includes two transistors, i.e., a selection transistor and a memory transistor configured to store data. A unit cell of a 2T EEPROM device will now be described below with reference to FIG. 1.

FIG. 1 is a cross-sectional view of a conventional EEPROM device.

Referring to FIG. 1, a floating gate 5, an oxide-nitride-oxide (ONO) layer 6, and a control gate electrode 7 are sequentially stacked on an active region defined at a semiconductor substrate 1. A selection gate electrode 10 is disposed on the active region adjacent to one side of the control gate electrode 7. The selection gate electrode 10 and the control gate electrode 7 are laterally spaced apart from each other.

A gate oxide layer 2 is interposed between the floating gate 5 and the active region and between the selection gate electrode 10 and the active region. A tunnel window 3 is disposed below the floating gate 5. A tunnel oxide layer 2a is interposed between the active region and the floating gate 5 in the tunnel window 3. The tunnel oxide layer 2a has a smaller thickness than the gate oxide layer 2. Electrons tunnel the tunnel oxide layer 2a to be stored in the floating gate 5 and/or to be ejected from the floating gate 5.

A source region 20 is formed at the active region adjacent to one side of the control gate electrode 7, and a drain region 22 is formed at the active region adjacent to one side of the selection gate electrode 10. A doping region 21 is formed at the active region between the control gate electrode 5 and the selection gate electrode 10. The doping region 21 extends laterally and downwardly toward the tunnel window 3.

The tunnel window 3 is formed by means of a patterning process including a photolithography process for the gate oxide layer 2 formed on the active region. With the recent trend toward higher integration density of semiconductor devices, the size of the EEPROM cell is decreasing. However, there is a limitation to how small the EEPROM cell can be because the tunnel window 3 is formed by means of a patterning process including a photolithography process. When the tunnel window 3 is formed with the minimum feature size that the photolithography process is capable of resolving, the active region is formed larger than the minimum feature size due to an alignment margin between the tunnel window 3 and the active region. Moreover, the control gate electrode is formed to have a larger linewidth than the minimum feature size.

As the EERPOM cell decreases in size, a ratio of an area of the tunnel window 3 to an area of the active region formed below the floating gate 5 increases. Thus, a difference between a program threshold voltage and an erase threshold voltage of the EEPROM cell may be reduced to decrease a sensing margin. Furthermore, power dissipation of the EEPROM device may increase.

### SUMMARY OF THE INVENTION

Exemplary embodiments of the present invention are directed to an EEPROM device. In an exemplary embodiment, the EEPROM device may include an active region defined at a semiconductor substrate and including a first region, a second region having a lower top surface than a top surface of the first region, and a sidewall disposed at the boundary between the first and second regions to connect top surfaces of the first and second regions to each other. A floating gate is disposed to cover the sidewall and the top surfaces of the first and second regions adjacent to opposite sides of the sidewall. A floating gate insulator is interposed between the floating gate and the active region. A blocking insulation pattern and a control gate electrode are sequentially stacked on the floating gate. The floating gate insulator includes a first portion interposed between the sidewall and the floating gate, a second portion interposed between the top surface of the first region and the floating gate, and a third portion interposed between the top surface of the second region and the floating gate. The second and third portions are each thicker than the first portion.

Exemplary embodiments of the present invention are directed to methods of forming an EEPROM device. In an exemplary embodiment, the method may include defining an active region on a semiconductor substrate, the active region including a first region, a second region having a lower top surface a top surface of than the first region, and a sidewall disposed at the boundary between the first and second regions to connect top surfaces of the first and second regions to each other. A gate insulator is formed on the active region, the gate insulator including a first portion covering the sidewall, a second portion covering the top surface of the first region, and a third portion covering the top surface of the second region. A floating gate, a blocking insulation pattern, and a control gate electrode are formed sequentially stacked on the gate insulator. The floating gate is formed to cover the sidewall and the top surfaces of the first and second regions adjacent to opposite sides of the sidewall. The second and third portions are each thicker than the first portion.

### BRIEF DESCRIPTION OF THE DRAWINGS

These and/or other aspects and features of the exemplary embodiments of the present invention will become apparent and more readily appreciated from the following description, taken in conjunction with the accompanying drawings of which:

FIG. 1 a cross-sectional view of a conventional EEPROM device;

FIG. 2 is a top plan view of an EEPROM device according to an exemplary embodiment of the present invention;

FIGS. 3A, 3B, and 3C are cross-sectional views taken along lines I-I′, II-II′, and III-III′ of FIG. 2, respectively;

FIGS. 4 through 11 are cross-sectional views, taken along the line I-I′ of FIG. 2 respectively, illustrating a method of forming an EEPROM device according to an exemplary embodiment of the present invention; and

FIG. 12 is a top plan view of a floating gate pattern of an EEPROM device according to an exemplary embodiment of the present invention.

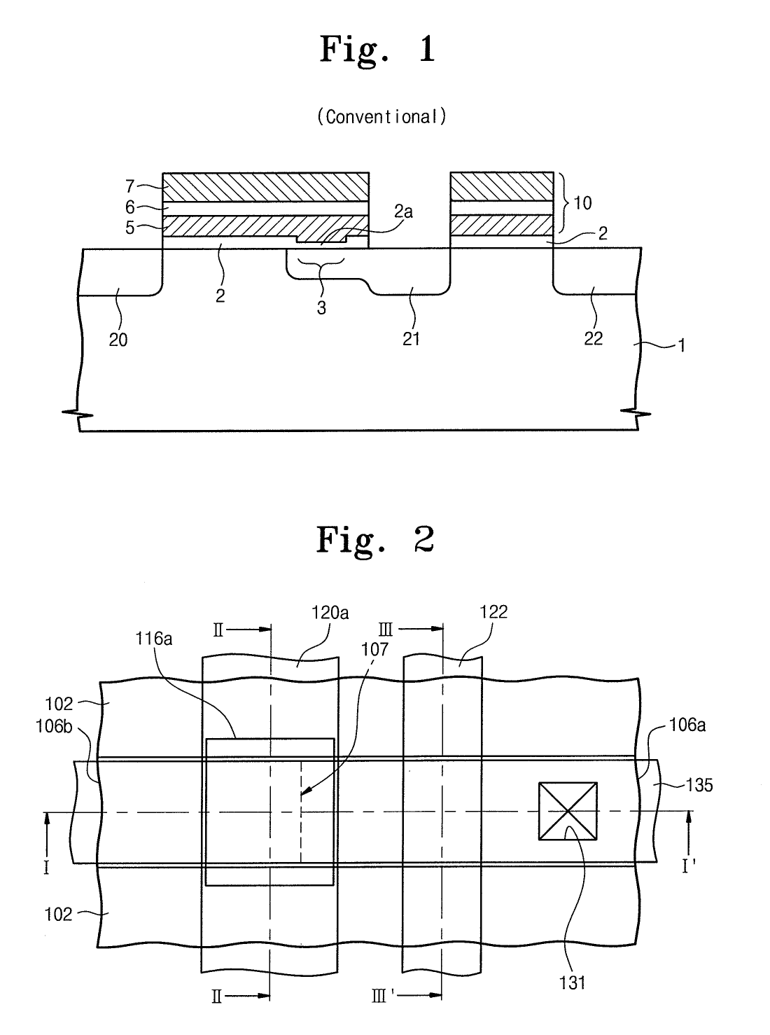

### DETAILED DESCRIPTION OF EXEMPLARY EMBODIMENTS

Exemplary embodiments of the present invention are described more fully bellow with reference to the accompanying drawings, in which preferred embodiments of the invention are shown. This invention, however, may be embodied in many different forms and should not be construed as limited to the exemplary embodiments set forth herein. In the drawings, the thicknesses of layers and regions may be exaggerated for clarity. When a layer is referred to as being “on” another layer or substrate, it can be directly on the other layer or substrate, or intervening layers may also be present. Like numbers may refer to like elements throughout.

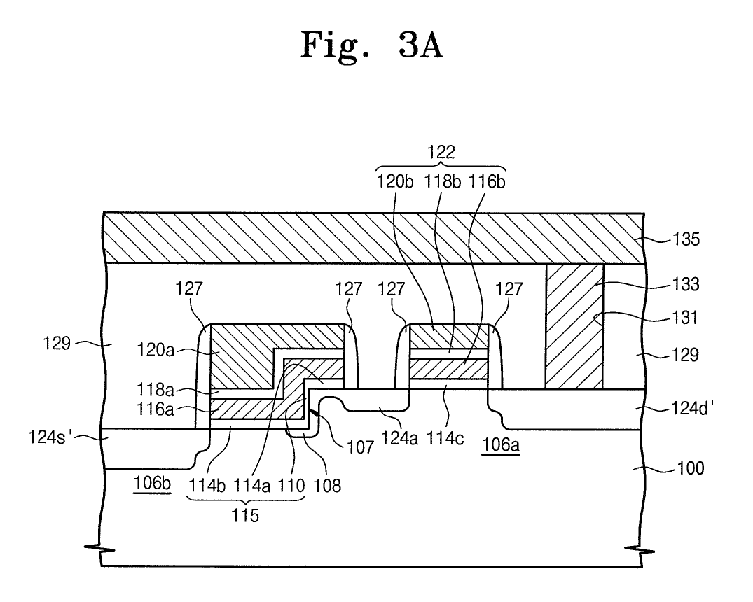

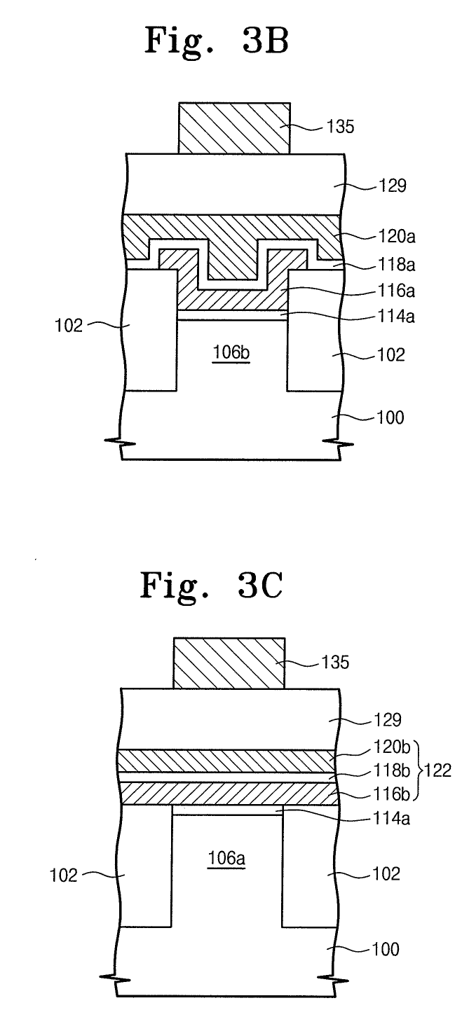

FIG. 2 is a top plan view of an EEPROM device according to an exemplary embodiment of the present invention. FIGS. 3A, 3B, and 3C are cross-sectional views taken along lines I-I′, II-II′, and III-III′ of FIG. 2, respectively.

Referring to FIGS. 2, 3A, 3B, and 3C, device isolation layers 102 are disposed at predetermined regions of a semiconductor substrate (hereinafter referred to as “substrate”) 100 to define active regions. The device isolation layer 102 may be a trench isolation layer. The active region includes a portion of the substrate 100. Specifically, the active region includes a first region 106a, a second region 106b, and a sidewall 107. A top surface of the second region 106b is lower than a top surface of the first region 106a. The top surface of the first region 106a is defined as a first top surface, and the top surface of the second region 106b is defined as a second top surface. The sidewall 107 is disposed at the boundary between the first regions 106a and the second region 106b, connecting one end of the first top surface and adjacent one end of the second top surface to each other. The top end of the sidewall 107 is connected to one end of the first top surface and the bottom end thereof is connected to one end of the second top surface. As illustrated, the sidewall 107 is perpendicular to the first top surface. Alternatively, the sidewall 107 may be inclined.

A floating gate 116a is disposed to cover the sidewall 107 and the first and second top surfaces adjacent to opposite sides of the sidewall 107. The floating gate 116a covers a portion of the first top surface adjacent to the sidewall 107 and a portion of the second top surface. A top surface of the device isolation layer 102 is proximate to the first top surface. A concave region may be disposed by the side of the first region 106a. A bottom surface of the concave region the second top surface, and an inner sidewall thereof include a top sidewall of the device isolation layer 102 and the sidewall 107. The floating gate 116a disposed on the second region 106b may be conformal along the bottom surface and the inner sidewall of the concave region. The floating gate 116a may cover the edge of the top surface of the device isolation layer 102 adjacent to the active region to secure an alignment margin between the floating gate 116a and the active region. The floating gate 116a may be made of doped silicon.

A floating gate insulator 115 is interposed between the floating gate 116a and the active region. The floating gate insulator 115 includes a first portion 110, a second portion 114a, and a third portion 114b. The first portion 110 is interposed between the floating gate 116a and the sidewall 107. The second portion 114a is interposed between the floating gate 116a and the first surface, and the third portion 114b is interposed between the floating gate 116a and the second top surface. Each of the second and third portions 114a and 114b is thicker than the first portion 110. The first portion 110 has a first surface and a second surface, which face each other. The first surface of the first portion 110 is in contact with the sidewall 107, and the second surface thereof is in contact with the floating gate 116a. The thickness of the first portion 110 is substantially equal to the shortest distance between the first and second surfaces of the first portion 110. The thickness of the second portion 114a may be substantially equal to that of the third portion 114b. Alternatively, the third portion 114b may include a portion having a different thickness from the second portion 114a. For example, a portion adjacent to the sidewall 107 of the third portion 114b may be slightly thinner than the second portion 114a. The first portion 110 having a relatively smaller thickness corresponds to a tunnel insulator. The first portion 110 of the floating gate insulator 115 may be made of oxide, for example thermal oxide. The second and third portions 114a and 114b of the floating gate insulator 115 may each be made of oxide, for example thermal oxide.

A control gate electrode 120a is disposed on the floating gate 116a. The control gate electrode 120a crosses over the active region. A blocking insulation pattern 118a is interposed between the control gate electrode 120a and the floating gate 116a. The blocking insulation pattern 118a and the floating gate 116a have a sidewall aligned with the sidewall of the control gate electrode 120a. The control gate electrode 120a may include conductive materials such as doped silicon, metal (e.g., tungsten or molybdenum), conductive metal nitride (e.g., titanium nitride or tantalum nitride), and/or metal silicide (e.g., tungsten silicide or cobalt silicide). The blocking insulation pattern 118a may be made of the same material as the floating gate insulator 115. In this case, the blocking insulation pattern 118a is thicker than the second portion 114a of the floating gate insulator 115. Alternatively, the blocking insulation pattern 118a may include a high-k dielectric having a higher dielectric constant than the floating gate insulator 115. The blocking insulation pattern 118a may include, for example, insulative metal oxide (e.g., hafnium oxide or aluminum oxide) that is a high-k dielectric.

A selection gate electrode 122 is disposed to cross over the first region 106a adjacent to one side of the gate electrode 120a. The selection gate electrode 122 is parallel with the control gate electrode 120a. The selection gate electrode 122 and the control gate electrode 120a are laterally spaced apart from each other. The selection gate electrode 122 includes a bottom gate 116b and a top gate 120b that are stacked in the order listed. The bottom and top gates 116b and 120b, respectively, extend in parallel with the control gate electrode 120a, and are line-shaped. As illustrated, a remnant pattern 118b may be disposed between the bottom and top gates 116b and 120b. The remnant pattern may be made of the same material as the blocking insulation pattern 118a. If the remnant pattern 118b is present, the bottom and top gates 116b and 120b may be electrically connected to each other by a butting contact (not shown). The butting contact may be disposed at the end of the selection gate electrode 122. The butting contact is a contact structure connected to the bottom gate 116b as well as the top gate 120b. Alternatively, the remnant pattern 118b may be omitted and the top gate 120b may be in direct contact with the top surface of the bottom gate 116b. The bottom gate 116b may be made of the same material as the floating gate 116a. The top gate 120b may be made of the same material as the control gate electrode 120a.

A selection gate insulator 114c is interposed between the selection gate electrode 122 and the first top surface of the first region 106a. The selection gate insulator 114c is thicker than the first portion 110 of the floating gate insulator 115. The selection gate insulator 114c has substantially the same thickness as the second portion 114a of the floating gate insulator 115. The selection gate insulator 114c is made of the same material as the second portion 114a of the floating gate insulator 115.

A tunnel doping region 108 extends into the active region from the sidewall 107. One end of the tunnel doping region 108 may extend beneath the first top surface below the floating gate 116a, and the other end thereof may extend beneath the second top surface adjacent to the sidewall 107. The first portion of the floating gate insulator 115 is interposed between the tunnel doping region 108 and the floating gate 116a.

A first dopant doping region 124a is formed at the first region 106a between the control gate electrode 120a and the selection gate electrode 122. The first dopant doping region 124a is in contact with the tunnel doping region 108. Dopants in the first dopant doping region 124a have the same conductivity type as dopants in the tunnel doping region 108. Accordingly, the first dopant doping region 124a and the tunnel doping region 108 are electrically connected to each other. A second dopant doping region 124s′ is formed at the second region 106b adjacent to one side of the control gate electrode 120a, and a third dopant doping region 124d′ is formed at the first region 106a adjacent to one side of the selection gate electrode 122. The second dopant doping region 124s′ corresponds to a source region, and the third dopant doping region 124d′ corresponds to a drain region. The selection gate electrode 122 is disposed on the first region 106a between the first dopant doping region 124a and the third dopant doping region 124d′. The second and third dopant doping regions 124s′ and 124d′ are doped with dopants of the same conductivity types. The second dopant doping region 124s′ is apart from the tunnel doping region 108. A surface of the second region 106b between the second dopant doping region 124s′ and the tunnel doping region 108 corresponds to a channel region below the floating gate 116a.

Gate spacers 127 may be disposed on both sidewalls of the control gate electrode 120a and the floating gate 116a and both sidewalls of the selection gate electrode 122. The gate spacer 127 may include oxide, nitride, and/or oxynitride. The second and third dopant doping regions 124s′ and 124d′ may be a lightly doped drain (LDD) structure including a first concentration region and a second concentration region. The first concentration region may be disposed below the gate spacer 127. In this case, the first dopant doping region 124a may have substantially the same dopant concentration as the first concentration region. Alternatively, the first dopant doping region 124a may have substantially the same LDD structure as the second and third dopant doping regions 124s′ and 124d′.

An interlayer dielectric 129 covers the entire surface of the substrate 100. The interlayer dielectric 129 may be made of oxide. A contact plug 133 fills a contact hole 131, which is formed to expose the third dopant doping region 124d′, through the interlayer dielectric 129. A bitline 135 is disposed on the interlayer dielectric 129 to cross over the control gate electrode 120a and the selection gate electrode 122. The bitline 135 is in contact with the contact plug 133 to be electrically connected to the third dopant doping region 124d′. The contact plug 133 is made of a conductive material. The contact plug 133 may include, for example, doped silicon, metal (e.g., tungsten, titanium, tantalum, etc.), metal silicide (e.g., titanium silicide, tantalum silicide, etc.), and/or conductive metal nitride (e.g., titanium nitride, tantalum nitride, tungsten nitride, etc.). The contact plug 133 may be omitted, and the bitline 135 may extend downwardly to fill the contact hole 131.

According to the above-described EEPROM device, the first portion 110 of the floating gate insulator 115 is thinner than the second and third portions 114a and 114b of the floating gate insulator 115. Thus, as described above, the first portion 110 of the floating gate insulator 115 is used as a tunnel insulator. For example, charges tunneling the floating gate insulator 115 to perform a program operation and/or an erase operation tunnel the first portion 110. Since the second and third portions 114a and 114b of the floating gate insulator 115 are each thicker than the first portion 110, it is substantially possible to prevent the charges from tunneling through the second and third portions 114a and 114b. Therefore a height of the sidewall 107 is regulated to reduce a tunneling area of the charges, which makes it possible to enhance programming and/or erasing efficiency. As a result, a sensing margin is improved to achieve an EEPROM device having superior characteristics.

A plane area defined by the tunneling area and occupied by the sidewall 110 may be substantially smaller than a conventional tunnel window. For example, a linewidth of the control gate electrode 120a is defined as the minimum feature size that a photolithography process is capable of resolving, achieving a highly integrated EEPROM device.

As described above, the charges tunnel the first portion 110 to be stored in the floating gate 116a or emitted from the floating gate 116a. The tunneling of the charges is done by means of Fowler-Nordheim tunneling (FN tunneling). Thus, the tunneling area of the charges may be more defined within the first portion 110. The charges tunneling the first portion 110 are the same type of charges as major carries in the tunnel doping region 108. For example, in the case where the major carriers in the tunneling doping region 108 are electrons, the charges tunneling the first portion 110 are also electrons. Alternatively, in the case where the major carriers in the tunnel doping region 108 are holes, the charges tunneling the first portion 110 are also holes.

A method of forming an EEPROM device according to exemplary embodiments of the present invention will now be described in detail with reference to accompanying drawings.

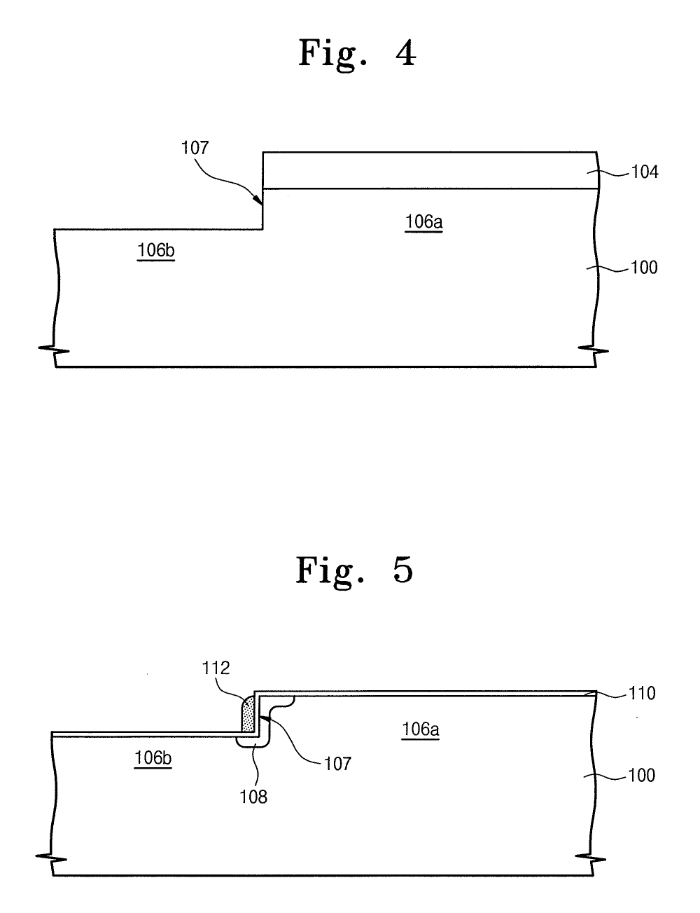

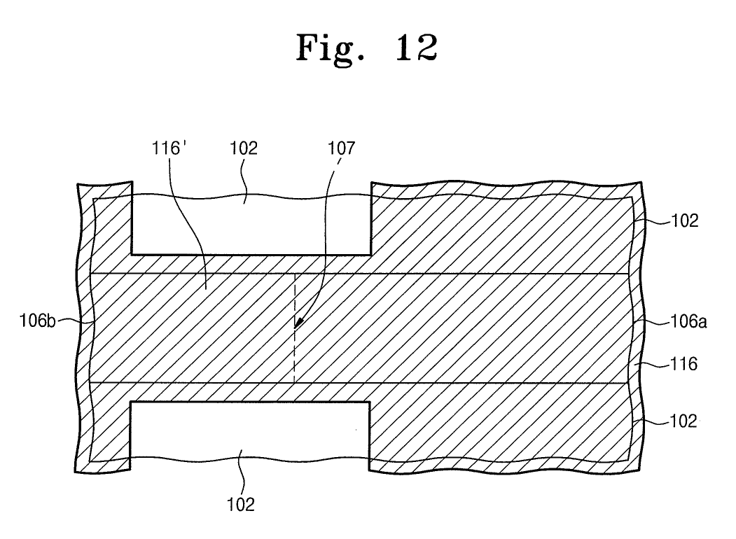

FIGS. 4 through 11 are cross-sectional views, taken along the line I-I′ of FIG. 2 respectively, illustrating a method of forming an EEPROM device according to an exemplary embodiment of the present invention. FIG. 12 is a top plan view of a floating gate pattern according to an exemplary embodiment of the present invention.

Referring to FIGS. 2 and 4, device isolation layers 102 are formed at predetermined regions of a substrate 100 to define preliminary active regions. The top surfaces of the preliminary active regions are coplanar with each other. The preliminary active regions have substantially the same height. A mask pattern 104 is formed to cover a portion of the preliminary active region, while the other portion of the preliminary active region is exposed. The mask pattern 104 is made of a material having an etch selectivity with respect to the substrate 100. The mask pattern 104 may include, for example, oxide, nitride, oxynitride, and/or photoresist.

Using the mask pattern 104 as an etch mask, the exposed portions of the preliminary active regions are anisotropically etched to define active regions. The active region includes a first region 106a, a second region 106b, and a sidewall 107. A top surface of the second region 106b is lower than that of the first region 106a. The sidewall 107 is disposed at the boundary between the first regions 106a and the second region 106b and connected to one end of the first region 106a and adjacent one end of the second region 4106b. For example, the top end of the sidewall 107 is connected to one end of the first region 106a, and the bottom end of the sidewall 107 is connected to one end of the second region 106b. As illustrated, the sidewall 107 may be perpendicular to the top surface of the first region 106a. Alternatively, the sidewall 107 may exhibit an inclined shape.

Referring to FIG. 5, the mask pattern 104 is removed. A trimming process may be performed for the substrate 100 to cure the etching damage of the second top surface and the sidewall 107. The trimming process includes a thermal oxidation process and a wet etching process performed to etch a thermal oxide layer. A surface of the active region is thermally oxidized to cure an etching damage and a thermal oxide layer formed on the surface of the active region is removed by means of the wet etching process to expose the surface of the active region. The trimming process may be repeated at least twice.

First dopant ions are selectively implanted into the substrate 100 to form a tunnel doping region 108. The tunnel doping region 108 is formed in the active region from the sidewall 107. A method of forming the tunnel doping region 108 is now described. Following the formation of the mask pattern 104, an ion implanting buffer layer is formed on the surface of the active region. The ion implanting buffer layer is made of thermal oxide. A photoresist pattern with an opening is formed to on the substrate 100. The opening of the photoresist pattern is formed to expose the sidewall 107. The opening of the photoresist pattern may be formed to partially expose the first and second top surfaces adjacent to the sidewall 107. Using the photoresist pattern as a mask, the first dopant ions are implanted to form the tunnel doping region 108. The dopant ions are obliquely implanted to the sidewall 107. The ion implanting buffer layer is removed by means of a wet etch to expose the surface of the active region.

The ion implanting buffer layer is made of thermal oxide, curing the etching damage (of the surface of the active region) caused by an etching process performed to define the second region 106b. Thus, while the trimming process is omitted, the formation and removal of the ion implanting buffer layer are done to cure the etching damage of the surface of the active region. Alternatively, the trimming process may be performed after the formation of the tunnel doping region 108.

A first insulation layer 110 is formed on the exposed surface of the active region. The first insulation layer 110 may be substantially conformal. The first insulation layer 110 may be made of oxide. The first insulation layer 110 may be formed by a semiconductor process including a thermal oxidation process, a chemical vapor deposition (CVD) process, and/or an atomic layer deposition (ALD) process.

An oxidation barrier layer is substantially formed on the first insulation layer 110. The oxidation barrier layer is anisotropically etched to form an oxidation barrier spacer 112 on the sidewall 107. The oxidation barrier spacer 112 covers the first insulation layer 110 formed on the sidewall 107. A bottom surface of the oxidation barrier spacer 112 covers a portion of the second top surface adjacent to the sidewall 107. The oxidation barrier spacer 112 has an etch selectivity with respect to the first insulation layer 110. The oxidation barrier spacer 112 is made of nitride and/or oxynitride.

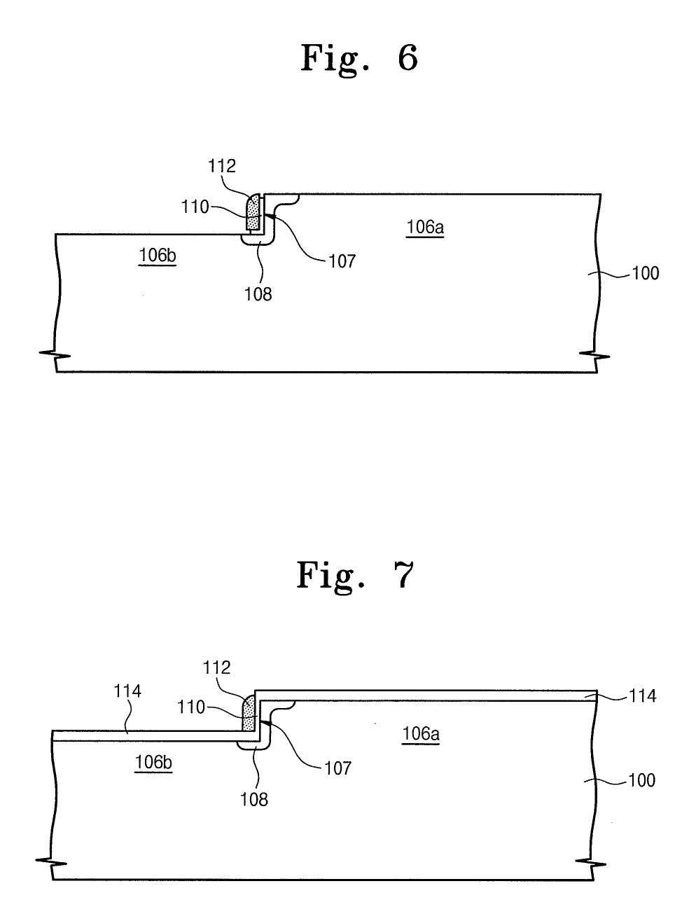

Referring to FIG. 6, using the oxidation barrier spacer 112 as a mask, the first insulation layer 110 on the first and second top surfaces is removed to expose the first and second top surfaces. At this point, the first insulation layer 110 remains on the sidewall 107 that the oxidation barrier spacer 112 covers. The removal of the first insulation layer 110 on the first and second top surfaces is done by a wet etch to prevent plasma etching damage of the exposed first and second top surfaces. Since the first insulation layer 110 is removed by the wet etch, both ends of the remaining first insulation layer 110 may be recessed. Thus, an under-cut region may be formed below the bottom surface of the oxidation barrier spacer 112, and one end of the remaining first insulation layer 110 adjacent to the first top surface may be lower than the first top surface.

Referring to FIG. 7, a thermal oxidation process is performed for the substrate 100 to form a second insulation layer on the exposed first and second top surfaces. The remaining first insulation layer 110 and the second insulation layer 114 constitute a gate insulator. The gate insulator includes a first portion, a second portion, and a third portion. The first portion is the first insulation layer 110 remaining on the sidewall 107. The second portion is the second insulation layer 114 formed on the first top surface, and the third portion is the second insulation layer 114 formed on the second top surface. As described above, each of the second and third portions is thicker than the first portion. A portion adjacent to the sidewall 107 of the third portion is also thicker than the remaining first insulation layer 110, for example, the first portion of the gate insulator. This results from the bird's beak of the second insulation layer 114 and/or the under-cut region caused by the thermal oxidation process. The third portion of the gate insulator below the oxidation barrier spacer 112 may be thinner than the second portion of the gate insulator.

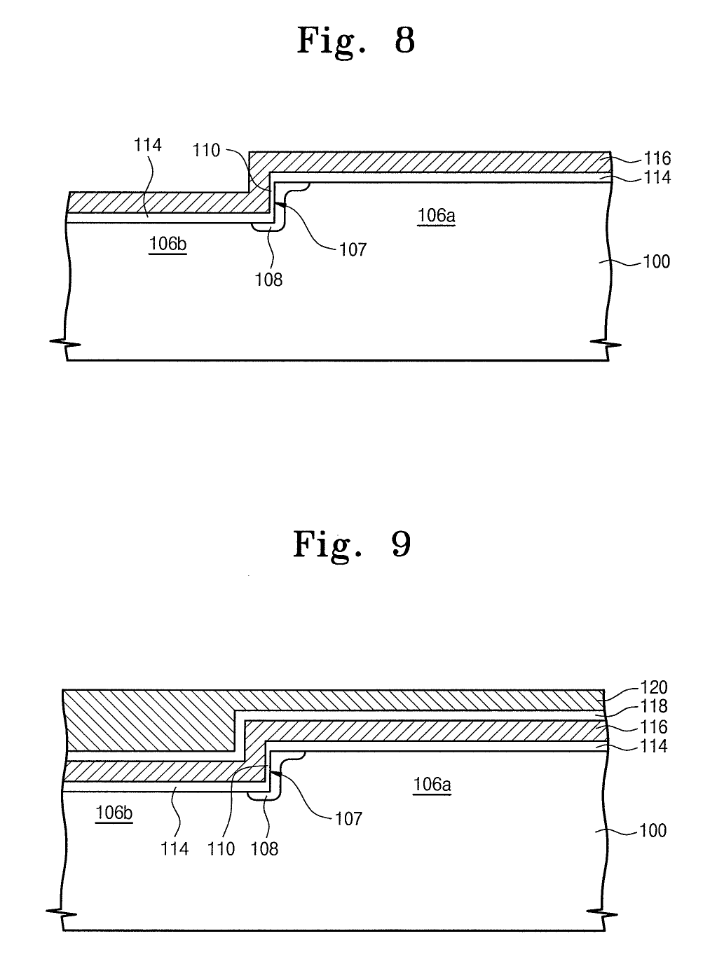

Referring to FIG. 8, the oxidation barrier spacer 112 is removed to expose the first portion of the gate insulator, for example, the remaining first insulation layer 110. The removal of the oxidation barrier spacer 112 is done by a wet etch to protect the surface of the first insulation layer 110 used as a tunnel insulator from the plasma etching damage.

A floating gate layer is formed on the entire surface of the substrate 100 including the gate insulator. The floating gate layer is patterned to form a floating gate pattern 116. A top plan view of the floating gate pattern 116 is illustrated in FIG. 12. The floating gate pattern 116 is described below in detail with reference to FIG. 12.

Referring to FIGS. 8 and 12, a portion 116′ of the floating gate pattern 116 exhibits a bar-shaped plane. The portion 116′ of the floating gate pattern 116 includes a portion formed as a floating gate in a subsequent process. The portion 116′ of the floating gate pattern 116 overlaps the top surface edge of the device isolation layer 102. A central portion of the device isolation layer 102 adjacent to opposite sides of the portion 116′ of the floating gate pattern 116 is exposed. Thus, a floating gate formed in a subsequent process may be separated from an adjacent floating gate. The floating gate pattern 116 may cover a region where a selection gate electrode is to be formed in a subsequent process. The floating gate layer may be substantially conformal. The floating gate layer is made of doped silicon.

Referring to FIG. 9, a blocking insulation layer 118 is formed on the entire surface of the substrate 100 including the floating gate pattern 116. A control gate conductive layer 120 is formed on the blocking insulation layer 118. The blocking insulation layer 118 is substantially conformal. The blocking insulation layer 118 may be made of oxide thicker than the first insulation layer 110. Alternatively, the blocking insulation layer 118 may be made of oxide-nitride-oxide (ONO). Alternatively, the blocking insulation layer 118 may include a high-k dielectric, e.g., insulative metal oxide such as hafnium oxide or aluminum oxide. The control gate conductive layer 120 may include conductive materials such as doped silicon, metal (e.g., tungsten or molybdenum), conductive metal nitride (e.g., titanium nitride or tantalum nitride), and/or metal silicide (e.g., tungsten silicide or cobalt silicide).

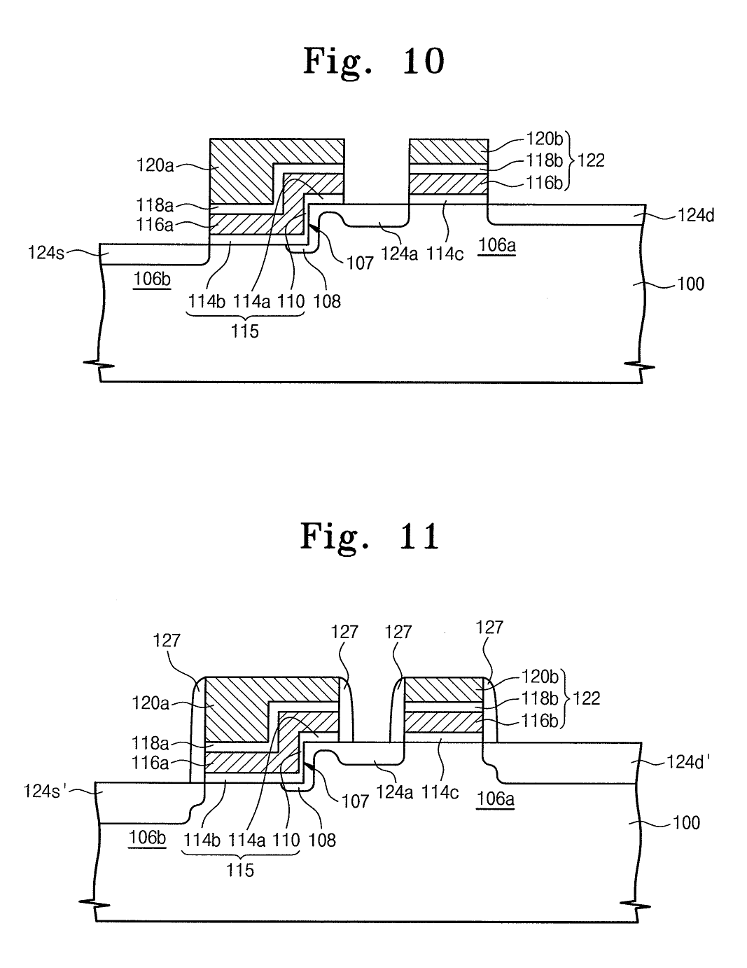

Referring to FIG. 10, the control gate conductive layer 120, the blocking insulation layer 118, the floating gate pattern 116, and the gate insulator are successively patterned to form a floating gate insulator 115, a floating gate 116a, a blocking insulation pattern 118a, and a control gate electrode 120a which are stacked in the order listed. A selection gate insulator 114c and a selection gate electrode 122 are sequentially formed on the first region 106a adjacent to one side of the control gate electrode 120a. The floating gate insulator 115 includes a first portion 110, a second portion 114a, and a third portion 114b. The first portion 110 corresponds to the above-described remaining first insulation layer 110. The second portion 114a corresponds to a portion adjacent to the sidewall 107 of the second insulation layer 114 on the first top surface, and the third portion 114b corresponds to a portion adjacent to the sidewall 107 of the second insulation layer 114 on the second top surface.

The selection gate insulator 114 corresponds to another portion of the second insulation layer 114 on the first top surface. The selection gate electrode 122 includes a bottom gate 116b, a remnant pattern 118b, and a top gate 120b which are stacked in the order listed. The bottom and top gates 116b and 120b are electrically connected to each other. If the remnant pattern 118b is present, a process may be further performed to form a butting contact which connects one end of the top gate 116b and one end of the bottom gate 120b to each other. Alternatively, before the formation of the control gate conductive layer 120, a process may be further performed to remove the blocking insulation layer 118 at the area where the selection gate electrode 122 is formed. In this case, the remnant pattern 118b is not formed, and the bottom and top gates 116b and 120b are in direct contact with each other.

Using the control gate electrode 120a and the selection gate electrode 122 as mask, second dopant ions are implanted into the active region to form first, second, and third dopant doping regions 124a, 124s, and 124d. The first to third dopant doping regions 124a, 124s, and 124d have the same shapes as described with reference to FIG. 2, FIG. 3A, FIG. 3B, and FIG. 3C.

Referring to FIG. 11, gate spacers 127 are formed on both sidewalls of the control gate electrode 120a and both sidewalls of the selection gate electrode 122. The gate spacer 127 is made of an insulating material. The gate spacer 127 may include oxide, nitride, and/or oxynitride.

Although not shown in the figures, an ion implanting mask pattern may be formed to cover the first dopant doping region 124a while the second and third dopant doping regions 124s and 124d are exposed. Using the ion implanting mask pattern, the control gate electrodes 120a and 122, and the gate spacer 127 as masks, third doping ions are implanted to form second and third dopant doping regions 124s′ and 124d′ of an LDD structure. While the ion implanting mask pattern is not formed, the third dopant ions may be implanted. In this case, the first dopant doping region 124a may be formed with the LDD structure. The first dopant ions are implanted to form the tunnel doping region 108. The second and third dopant ions are dopants having the same conductivity type.

An interlayer dielectric 129 illustrated in FIG. 3A is formed on the entire surface of the substrate 100. The interlayer dielectric 129 is patterned, forming a contact hole 131 illustrated in FIG. 3A to expose the third dopant doping region 124d′. A contact plug 133 illustrated in FIG. 3A is formed to fill the contact hole 131. A bitline 135 illustrated in FIG. 3A is formed. Thus, an EEPROM device illustrated in FIG. 2, FIG. 3A, FIG. 3B, and FIG. 3C may be achieved.

A plane area occupied by the sidewall 107 is smaller than the minimum feature size that a photolithography process is capable resolving. In the case where the sidewall 107 is perpendicular to the first top surface, the plane area occupied by the sidewall 107 may be zero. Thus, a highly integrated EEPROM device may be achieved. Further, the first portion 110 of the floating gate insulator 115 is formed thinner than the second and third portions 114a and 144b of the floating gate insulator 115 to define a charge-tunneling region within the sidewall 107. For example, the charge-tunneling area is reduced to enhance programming and/or erasing efficiency. Thus, an EEPROM device having superior characteristics may be achieved. The etched depth of a portion of the preliminary active region is regulated to make the area of the sidewall 107 smaller than an area made with the minimum features size that is a photolithography process is capable of resolving. Accordingly, programming and/or erasing efficiency may be enhanced.

As discussed above, an active region includes a first region, a second region having a lower top surface than the first region, and a sidewall disposed at the boundary between the first and second regions. A charge-tunneling region is defined within the sidewall to achieve a highly integrated EEPROM device having superior characteristics.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

What is claimed is:

1. An EEPROM device comprising:
an active region of a semiconductor substrate including a first region, a second region having a lower top surface than a top surface of the first region, and a sidewall disposed at a boundary between the first and second regions to connect top surfaces of the first and second regions to each other;
a floating gate disposed to cover the sidewall and the top surfaces of the first and second regions adjacent to opposite sides of the sidewall;
a floating gate insulator interposed between the floating gate and the active region; and
a blocking insulation pattern and a control gate electrode sequentially stacked on the floating gate,
wherein the floating gate insulator includes a first portion interposed between the sidewall and the floating gate, a second portion interposed between the top surface of the first region and the floating gate, and a third portion interposed between the top surface of the second region and the floating gate, the second and third portions each being thicker than the first portion.

2. The EEPROM device as set forth in claim 1, wherein charges tunnel through the first portion of the floating gate insulator to perform a program operation or an erase operation.

3. The EEPROM device as set forth in claim 1, further comprising:
a tunnel doping region extending into the active region from the sidewall;
a first dopant doping region formed at the first region adjacent to one side of the control gate electrode and connected to the tunnel doping region; and
a second dopant doping region formed at the second region adjacent to the other side of the control gate electrode.

4. The EEPROM device as set forth in claim 3, wherein charges tunnel the first portion of the floating gate insulator by means of Flower-Nordheim tunneling (FN tunneling).

5. The EEPROM device as set forth in claim 3, further comprising:
a third dopant doping region formed at the first region and spaced apart from the first dopant doping region;
a selection gate electrode disposed on the first region between the first dopant doping region and the third dopant doping region; and
a selection gate insulator interposed between the selection gate electrode and the top surface of the first region.

6. The EEPROM device as set forth in claim 5, wherein the selection gate insulator has substantially the same thickness as the second portion of the floating gate insulator.

7. The EEPROM device as set forth in claim 5, wherein the selection gate electrode includes a bottom gate and a top gate that are stacked, the bottom electrode being made of the same material as the floating gate; the top electrode being made of the same material as the control gate electrode; and the bottom and top electrodes being electrically connected to each other.

8. The EEPROM device as set forth in claim 1, wherein the sidewall is perpendicular or inclined to the top surface of the first region.

9. The EEPROM device as set forth in claim 1, wherein the second and third portions of the floating gate insulator have substantially the same thickness.

10. A method of forming an EEPROM device, comprising:
defining an active region on a semiconductor substrate, the active region including a first region, a second region having a lower top surface than a top surface of the first region, and a sidewall disposed at a boundary between the first and second regions to connect top surfaces of the first and second regions to each other;
forming a gate insulator on the active region, the gate insulator including a first portion covering the sidewall, a second portion covering the top surface of the first region, and a third portion covering the top surface of the second region; and
forming a floating gate, a blocking insulation pattern, and a control gate electrode sequentially stacked on the gate insulator, the floating gate formed to cover the sidewall and the top surfaces of the first and second regions adjacent to opposite sides of the sidewall, and the second and third portions each being thicker than the first portion.

11. The method as set forth in claim 10, wherein the forming a gate insulator comprises:
forming a first insulation layer on a surface of the active region;
forming an oxidation barrier spacer to cover a first insulation layer formed on the sidewall;
removing a first insulation layer of the first and second regions, using the spacer as a mask, to expose the top surfaces of the first and second regions;
performing a thermal oxidation process to form a second insulation layer on the exposed top surfaces of the first and second regions, the second insulation layer being thicker than the first insulation layer; and
removing the oxidation barrier spacer.

12. The method as set forth in claim 11, wherein the first insulation layer on the first and second regions is removed by a wet etch.

13. The method as set forth in claim 11, wherein the oxidation barrier spacer is removed by a wet etch.

14. The method as set forth in claim 11, wherein the first insulation is formed by a semiconductor process including a thermal oxidation process, a chemical vapor deposition (CVD) process, or an atomic layer deposition (ALD) process.

15. The method as set forth in claim 10, wherein the defining an active region comprises:
forming a device isolation layer at a predetermined region of the semiconductor substrate to define a preliminary active region;
forming a mask pattern to cover a portion of the preliminary active region while exposing another portion of the preliminary active region;
anisotropically etching the exposed portion of the preliminary active region using the mask pattern as an etch mask; and
removing the mask pattern.

16. The method as set forth in claim 15, wherein the sidewall is formed perpendicular or inclined to the top surface of the first region.

17. The method as set forth in claim 10, further comprising, before forming the gate insulation layer:
forming a tunnel doping region extending into the active region from the sidewall.

18. The method as set forth in claim 10, further comprising:
forming a selection gate electrode on the second portion of the gate insulator, the selection gate electrode being laterally spaced apart from the control gate electrode.

19. The method as set forth in claim 18, wherein the selection gate electrode includes a bottom gate and a top gate that are stacked, the bottom and top gates being electrically connected to each other, and the bottom gate being made of the same material as the floating gate and the top gate being made of the same material as the control gate electrode.

20. The method as set forth in claim 18, further comprising:
implanting dopant ions, using the control gate electrode and the selection gate electrode to form a dopant doping region.
